(19) United States
(12) Patent Application Publication
(10) Pub. No.: US 2006/0160033 A1
(43) Pub. Date: Jul. 20, 2006

(54) Method for printing by printed pattern and production equipment for printing printed pattern

(75) Inventor: Mitsuasa Takahashi, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC LCD TECHNOLOGIES, LTD.

(21) Appl. No.: 11/334,372

(22) Filed: Jan. 19, 2006

(30) Foreign Application Priority Data
Jan. 20, 2005 (JP) 12783/2005

(51) Int. Cl. G03F 7/00

(52) U.S. Cl. 430/323

(57) ABSTRACT

A method for printing a printed pattern, comprising the steps of a printed pattern forming process for forming the printed pattern such as a resist made of an etching resistant member on an etching film formed on a substrate, and thereafter, a thinning process for thinning the resist in a thickness direction by using dry etching such as plasma ashing and wet etching such as developing processing before carrying out etching by using the printed pattern as a mask, and an etching process for etching an etching film by using the thinned printed pattern as the mask.

### BACKGROUND OF THE INVENTION

1. Field of the Invention

The present invention relates to a method for printing by using a printed pattern and production equipment for printing the printed pattern, and particularly, to a method for manufacturing a liquid crystal display (hereinafter referred to as LCD) device and production equipment therefor.

2. Description of the Related Art

As a display device of an audio-visual (AV) machine and an office automation (OA) machine, a LCD device has been widely used because of its merits including a thin thickness, a light weight, a low power consumption, and the like.

Among the LCDs, an active-matrix LCD using a thin film transistor (TFT) as a switching element has been widely used.

This active-matrix LCD includes a liquid crystal panel for displaying information, a backlight unit for irradiating light onto the back surface of the liquid crystal panel, a backlight chassis for supporting and fixing the backlight unit. The liquid crystal panel has a configuration comprising an active-matrix substrate (hereinafter referred to as a TFT substrate) on which the switching elements such as TFTs are arranged in a matrix form, a color filter substrate on which a color filter, and the like, is formed, and a liquid crystal which is sandwiched between the TFT substrate and the color filter substrate.

Several processes are needed to form the above-described TFT substrate. For example, in addition to the processes of forming gate lines on a transparent insulating substrate, forming a translucent semiconductor layer such as amorphous silicon via a gate insulating film, and forming source/drain lines, the processes of forming contact holes in a passivation film, forming pixel electrodes, and the like, are also needed.

Here, to reduce initial cost of the LCD, the reduction of production manhour and the improvement of yielding percentage, are important because, resist pattern formation is carried out for each of the above processes. Therefore, to reduce the production manhour, it is effective to reduce the number of production manhour required for the resist pattern formation.

This resist pattern is generally formed by carrying out exposing processing and developing processing in which a photo-resist and photomask are used. However, a method for forming a pattern by using a photo-resist and a photolithography method requires a number of production manhour, thereby manufacturing cost becomes higher. Therefore, there is provided a simplified method of the printing method capable of reducing the initial manufacturing cost by reducing the number of processes.

These simplified processes are disclosed in, for example, Japanese Published Unexamined Application 2004-214593 (p5-7, FIG. 1), Japanese Published Unexamined Application 2004-212985 (p6-9, FIG. 1) , and Japanese Published Unexamined Application 2004-46144 (p7-10, FIG. 1), respectively. In the disclosed processes, a resist is coated onto an upper portion of a cliché in which a concave groove is formed in a position corresponding to the position of a pattern to be formed on a substrate so that the resist is filled into an inside of the groove, and transferred to a print roll which rotates on the surface of the cliche. After that, the resist is again transferred to an etching object layer formed on the substrate by bringing the resist transferred to the surface of the print roll into contact with the surface of the etching object layer formed on the substrate.

By using the above-described printing method, the reduction of initial cost is possible since the number of processes can be reduced compared with a case where the photolithography method is used. However, in the printing method, an undesired resist tends to be residual on the surface of the cliche at the time of filling the resist into the groove, and pieces of the resist scatter at the time of transferring the resist. Thus, the resist tends to adhere to a region other than a proper region where a pattern is formed, and the developing processing (equivalent to resist etching) included in the photolithography method is not included therein. Therefore, the resist adhered to the region other than the proper region is not removed and a foundation film in the lower portion of the resist adhered by an etching thereafter becomes residual. As a result, there are problems in that drawbacks such as line short circuit, point defect by pattern residual, and the like, tend to be caused.

Specifically, as shown in FIG. 1A, an etching film 2 to be etched is formed on a transparent insulating substrate 1. If a resist 3 is formed on the etching film 2 by the printing method, in some cases, a resist 4 adhered to a region other than the proper region where a pattern is formed becomes residual. As shown in FIG. 1B, if the etching is carried out while the adhered resist 4 remains thereon, the etching film 2 in the lower portion of the adhered resist 4 remains as a residue 2a without being etched. This residue 2a causes a problem in that the drawbacks such as line short circuit or point defect are caused to deteriorate yielding percentage.

### SUMMARY OF THE INVENTION

The present invention has been made in view of the forgoing. Accordingly it is an object of the present invention to provide a processing method using a printed pattern and production equipment for printing the printed pattern, particularly, a method for manufacturing a liquid crystal panel, and production equipment therefor, by which the generation of drawbacks will be suppressed.

To achieve the above objectives, in one aspect, the present invention relates to a processing method comprising at least a printing process for forming by a printing method a printed pattern made of an etching resistant member on an etching film formed on a substrate, a thinning process for thinning the printed pattern by dry etching or wet etching, and an etching process for etching the etching film by using the thinned printed pattern as a mask.

In the present invention, the etching resistant member can be a photo-resist or non-photosensitive resist.

In another aspect, the present invention relates to a processing method comprising at least a printing process for forming by a printing method a printed pattern made of a conductive member incorporating conductive particles on a substrate, and a thinning process for thinning the printed pattern by dry etching or wet etching.

In another aspect, the present invention relates to a configuration comprising a baking process for applying heat to the printed pattern at the timing of at least either between the printing process and the thinning process, or after the thinning process.

In another aspect, the present invention relates to a configuration comprising a thinning process carried out under the conditions that an etching resistant member adhered to a region other than the region where the printed pattern is formed, or a conductive member can be removed or reduced in size.

In another aspect, the present invention relates to dry etching and wet etching that preferably includes plasma ashing and developing processing, respectively.

In another aspect, the present invention relates to a method for manufacturing a liquid crystal display device or an organic EL display device by using at least one of the methods described above.

In another aspect, the present invention relates to production equipment, in which a printed pattern made of a conductive member incorporating an etching resistant member or conductive particles is formed on the substrate, comprising a thinning processing means for thinning the printed pattern by dry etching or wet etching.

In another aspect, the present invention relates to a baking means for applying heat to the printed pattern.

Thus, according to the configurations of the present invention, the etching resistant member or the conductive member adhered to the undesired region can be effectively removed or reduced in size, thereby the drawbacks such as line short circuit, point defect by pattern residual can be suppressed.

As described above, in the present invention, since the thinning processing such as the plasma ashing or the developing processing for thinning the etching resistant member is added after the printed pattern is formed by using the etching resistant member such as the resist and before the etching process is carried out by using the printed pattern as the mask, the etching resistant member can be removed or reduced in size so that the etching film can be completely removed from the lower portion of the adhered etching resistant member or can be reduced in size even when the etching resistant member is adhered to the undesired region.

In addition, since the thinning processing such as the plasma ashing or developing processing for thinning the conductive member is added after the printed pattern is formed by using the conductive member incorporating the conductive particles, the adhered conductive member can be removed or reduced in size even when the conductive member adheres to the undesired region.

According to the present invention, the drawbacks such as line short circuit, point defect by pattern residue can be suppressed, and the reduction of production manhour and the improvement of yielding percentage can be achieved at the same time.

### BRIEF DESCRIPTION OF THE DRAWINGS

The present invention will-now be described, by way of example, with reference to the accompanying drawings, in which:

FIG. 1A is a cross-sectional diagram of a process showing a processing method using a conventional printed pattern;

FIG. 1B is a cross-sectional diagram of a process showing a processing method, following FIG. 1A, using the conventional printed pattern;

FIG. 1C is a cross-sectional diagram of a process showing a processing method, following FIG. 1B, using the conventional printed pattern;

FIG. 2A is a cross-sectional diagram of a process showing a processing method using a printed pattern according to an embodiment of the present invention;

FIG. 2B is a cross-sectional diagram of a process showing a processing method, following FIG. 2A, using the printed pattern according to an embodiment of the present invention;

FIG. 2C is a cross-sectional diagram of a process showing a processing method, following FIG. 2B, using the printed pattern according to an embodiment of the present invention;

FIG. 2D is a cross-sectional diagram of a process showing a processing method, following FIG. 2C, using the printed pattern according to an embodiment of the present invention;

FIG. 3 is a cross-sectional diagram of a process showing a method for manufacturing a TFT substrate according to a first embodiment of the present invention;

FIG. 4 is a cross-sectional diagram of a process showing the method for manufacturing the TFT substrate according to the first embodiment of the present invention;

FIG. 5 is a cross-sectional diagram of a process showing the method for manufacturing the TFT substrate according to the first embodiment of the present invention;

FIG. 6 is a cross-sectional diagram of a process showing the method for manufacturing the TFT substrate according to the first embodiment of the present invention;

FIG. 7 is a cross-sectional diagram of a process showing the method for manufacturing the TFT substrate according to the first embodiment of the present invention;

FIG. 8 is a cross-sectional diagram of a process showing the method for manufacturing the TFT substrate according to the first embodiment of the present invention;

FIG. 9 is a cross-sectional diagram of a process showing the method for manufacturing the TFT substrate according to the first embodiment of the present invention;

FIG. 10 is a cross-sectional diagram of a process showing the method for manufacturing the TFT substrate according to the first embodiment of the present invention; and

FIG. 11 is a configuration diagram of printing equipment comprising a thinning processing unit according to a second embodiment of the present invention.

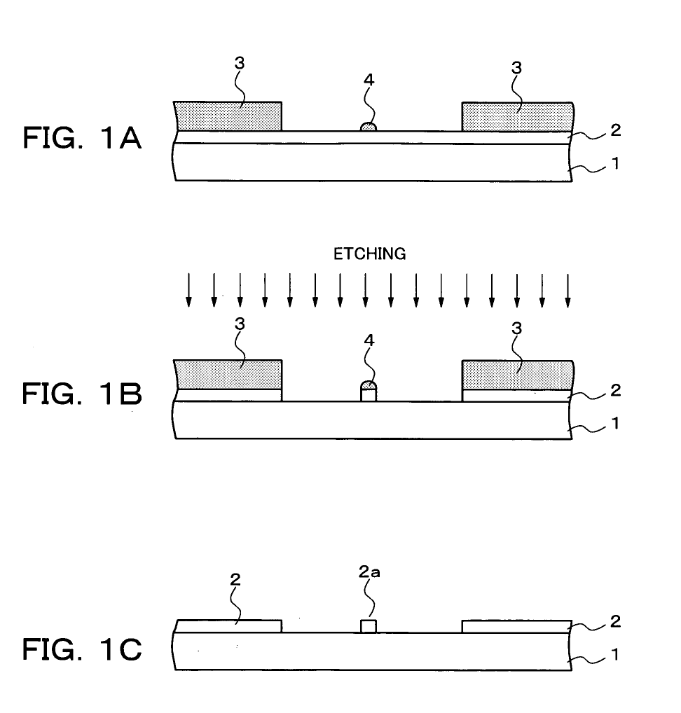

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

First, in the present invention, a printed pattern such as a resist pattern is formed on an etching film. Next, before carrying out a processing such as etching by using the printed pattern as a mask, a thinning processing is carried out to thin the resist in a thickness direction thereof by using dry etching (for example, plasma ashing) or wet etching (for example, developing processing). Therefore, the drawbacks caused at the time of using the printing method are substantially reduced.

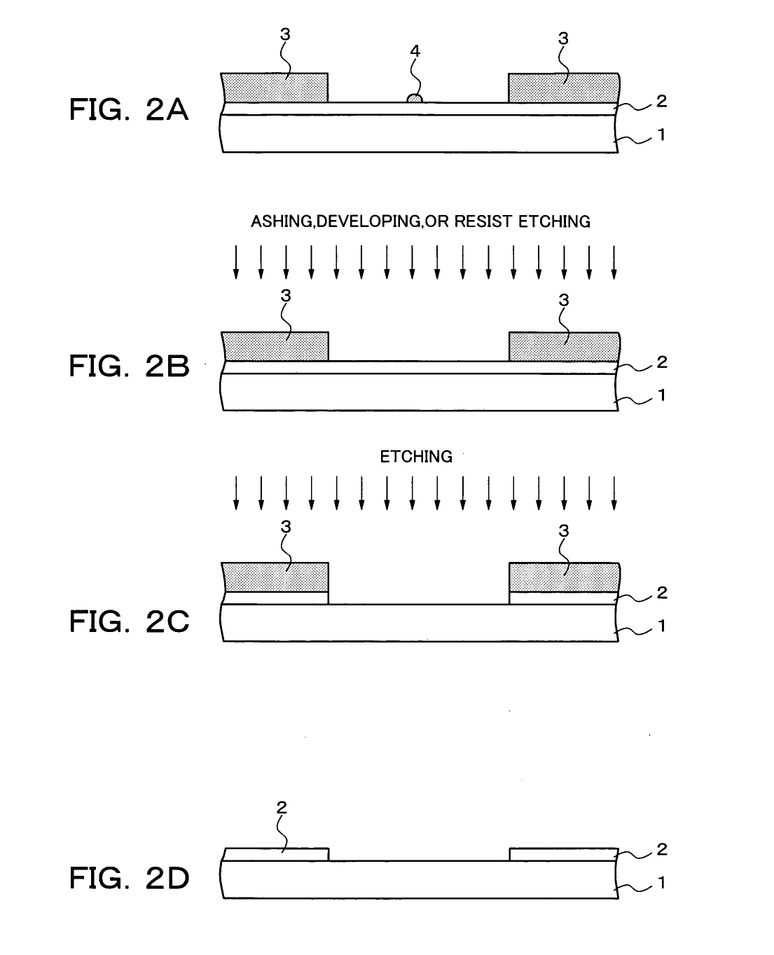

Specifically, as shown in FIG. 2A, chromium (Cr) having a thickness of approximately 140 nm is deposited as an etching film 2 by a spattering method. Next, a resist 3 having a thickness of 2 μm is printed by a printing method such as off-set printing or inkjet printing. At this time, as described above, the printing method tends to cause the resist to adhere to an undesired region at the time when the resist is transferred, thereby causing the drawbacks in the following processes.

Therefore, as shown in FIG. 2B, the adhered resist 4 is removed by carrying out a processing for thinning the resist by plasma ashing, developing processing, or other etching methods after the resist is printed. The conditions (time, temperature, kinds of processing) of this resist thinning processing are not particularly limited. That is, the conditions only have to be capable of being sufficiently small such that the adhered resist 4 does not cause a problem in the following processes, and the conditions can be appropriately set according to the size of the resist 4, the thickness of the resist 3, or the like. In addition, the resist 3 can be a photo-resist (a resist sensitive to light, ultraviolet ray, electronic ray, and the like, are collectively referred to as a photo-resist) used by a photolithography process. In addition, a resist excluding a photosensitive agent (hereinafter, referred to as a non-photosensitive resist) can be also used as well as other members, in place of the resist, such as a resin which is capable of being printed by the printing method, resistant to the following processes, and capable of being removed by dry etching or wet etching.

Next, as shown in FIG. 2C, the resist 3 is removed after the exposing etching film 2 is removed by using the dry etching or the wet etching. Thus, as shown in FIG. 2D, a preferred pattern in which the etching film 2 in the original region which should be etched is removed, can be formed.

It should be noted that the above-described processes are only examples, and a baking processing can be carried out before the thinning processing or before etching the etching film 2, depending on situations.

### FIRST EXEMPLARY EMBODIMENT OF THE PRESENT INVENTION

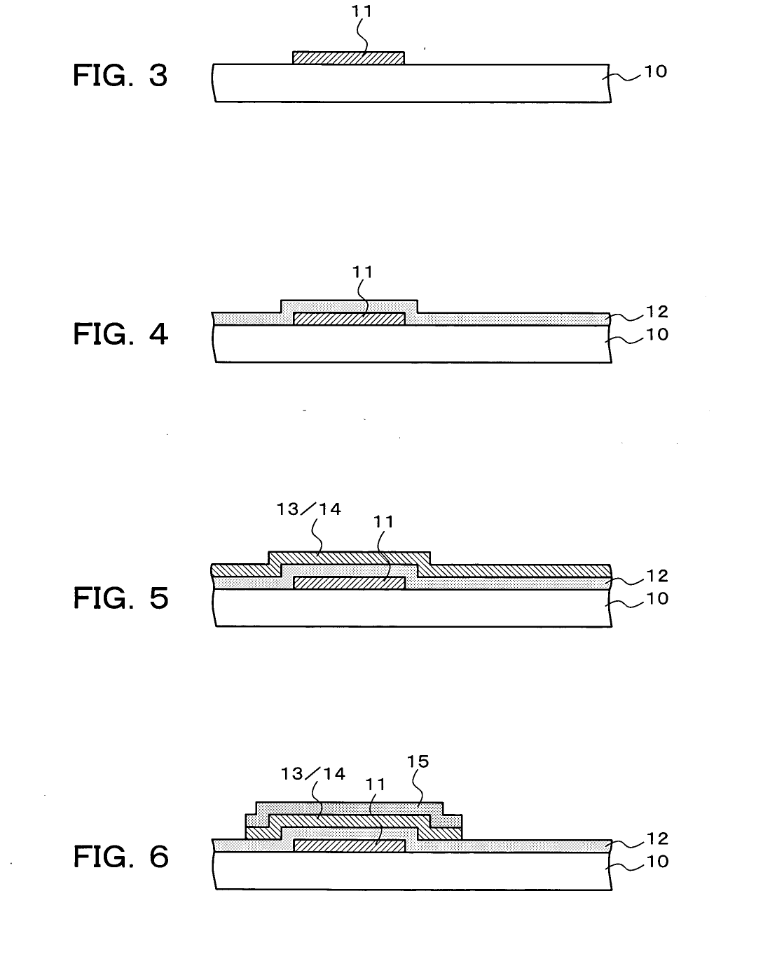

To further describe'the above embodiments of the present invention in detail, a method for manufacturing a liquid crystal panel according to the present invention will de described by referring to FIGS. 3 to 9. FIGS. 3 to 9 are cross-sectional diagrams showing the processes of manufacturing a TFT substrate for LCD to which a thinning processing according to the present invention is applied. It should be noted that, in the present embodiment, a case where the thinning processing according to the present invention is applied to the method for manufacturing the TFT substrate for LCD, is described, but the thinning processing according to the present invention can be applied to an arbitrary manufacturing method including a process in which a printed pattern formed by a printing method is used for etching.

The TFT substrate for LCD is generally provided with a plurality of gate lines extending in a predetermined direction, and a plurality of drain lines extending in a direction substantially perpendicular to the gate lines via a gate insulator film. Further, the TFT substrate for LCD is provided with a TFT configured in the vicinity of the crossover of the gate lines and the drain lines, and pixel electrodes to be connected to source lines of the TFT via contact holes formed in a passivation film. Detailed description of the method for manufacturing the TFT substrate will be given below by referring to FIGS. 3 to 9.

FIG. 3 is a cross-sectional diagram showing a process for forming gate lines. According to FIG. 3, a metal, for example, Cr, to be a gate line 11 having a thickness of approximately 200 nm is disposed by the spattering method on a transparent insulating substrate 10 made of glass, plastic, or the like. After that, a resist is formed by the printing method, and is baked, followed by which the resist adhered to a region other than the gate line 11 is removed or reduced in size by the thinning processing shown in FIG. 2B. Next, the exposing Cr is etched by the wet etching or the dry etching, and the resist is removed, thereby forming the gate line 11. It should be noted that the gate line 11 can be also formed by printing a paste incorporating conductive metal particles and baking the paste after carrying out the thinning processing of the present invention for the paste. In addition, from the viewpoints of adhesiveness to the substrate, workability, and reliability, a suitable resist is a photo-resist used for photolithography process, and the resist excluding the photosensitive agent are further advantageous in price. In addition, the thickness of the thinned resist is preferred to be 80% or smaller of the printed thickness. If the resist is removed more than the above percentage, pattern collapse is often caused, thereby the optimum value is in the vicinity of 50%.

FIG. 4 is a cross-sectional diagram showing a process for forming a gate insulating film with a silicon oxide having a thickness of approximately 100 nm and a silicon nitride (SiN) having a thickness of approximately 400 nm, which is disposed by the spattering method or Chemical Vapor Deposition (CVD) method.

FIG. 5 is a cross-sectional diagram showing a process for forming a semiconductor layer. First, amorphous silicon (hereinafter, a-Si) 13 having a thickness approximately 250 nm is disposed on the gate insulating film by a Low-Pressure (LP)-CVD method. Similarly, n⁺a-Si 14 having a thickness of 50 nm is disposed by the LP-CVP method. It should be noted that, in general, the SiN, a-Si 13, and the n⁺a-Si 14, which are one part of the gate insulating film, are continuously disposed in the same equipment.

FIG. 6 is a cross-sectional diagram showing a process for forming a pattern of the semiconductor layer. First, a resist 15 is printed by using the printing method, and the thinning processing shown in FIG. 2B is carried out to remove the resist adhered to an undesired region or reduce the size thereof. Next, the exposing a-Si 13/n⁺a-Si 14 is etched by Reactive Ion Etching (RIE), and the island-shaped semiconductor layer is formed by removing the resist. It should be noted that similarly to the process for forming the gate line, the photo-resist used for the photolithography process can be used as the non-photosensitive resist can used. In other words, a preferred thickness of the thinned resist is 80% or smaller than the printed thickness, and to be in the vicinity of 50% is preferred.

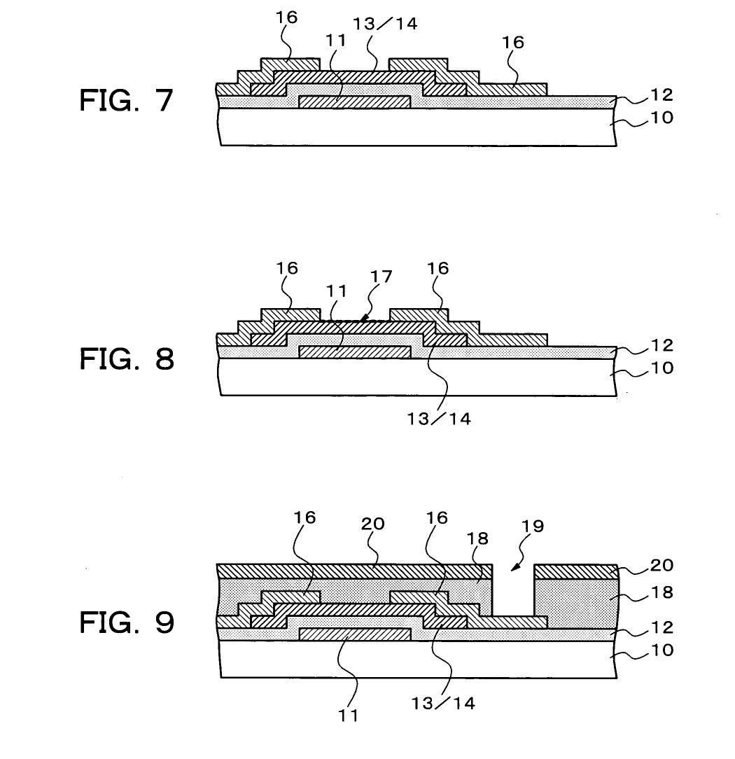

FIG. 7 is a cross-sectional diagram showing a process for forming a source/drain line (hereinafter, S/D line). A metal to be the S/D line, for example Cr, is disposed by the spattering method to have a thickness of approximately 140 nm, and the resist having a thickness of approximately 2 μm is formed by the printing method. After baking the resist, the resist adhered to an undesired region is removed by the resist thinning processing or reduced in size to cause the resist residual to be approximately 1 μm. After baking the resist again, the exposing Cr is etched by the wet etching or the dry etching to remove the resist, thereby forming the S/D line 16.

FIG. 8 is a cross-sectional diagram showing a process for channel etching for etching approximately 130 nm of the n⁺a-Si by using the S/D line 16 as a mask. This etching is possible by the RIE method, but the plasma CVD is more preferred from the viewpoint of the TFT characteristics.

FIG. 9 is a cross-sectional diagram showing a process for forming a contact hole. After the SiN having a thickness of approximately 200 nm is formed as a passivation film 18 by the spattering method or the CDV method, the resist 20 is printed by the printing method. The resist thinning processing shown in FIG. 2B is carried out to remove the resist adhered to an undesired region or to reduce the size thereof before the resist is baked again. Then, the contact hole 19 connected to the source line is formed by the wet etching and the RIE method. It should be noted that the passivation film 18 can be an organic film such as acryl or have a laminated structure of an inorganic film and an organic film. In addition, since the resist often remains during the process of forming the contact hole 19, the contact hole 19 can be formed by a general photolithography process using the photo-resist and the photo-mask in a case where the tact time of the printing machine is long.

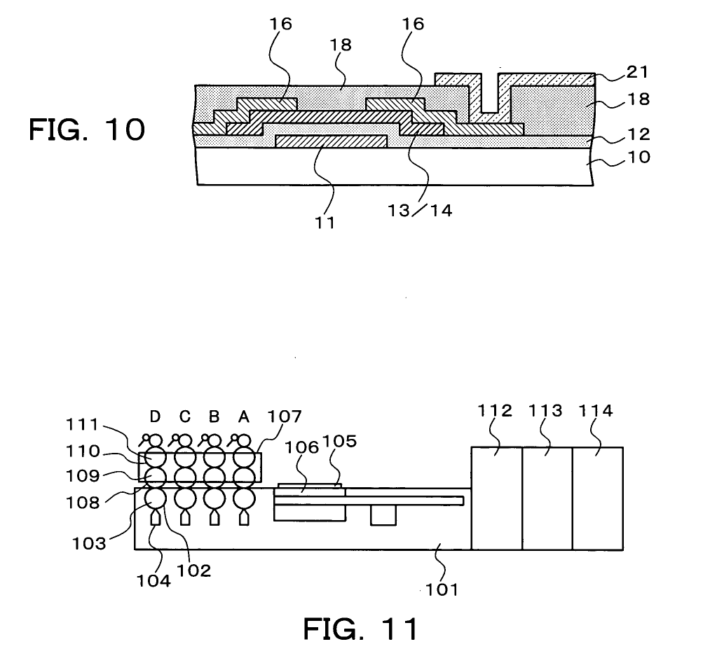

FIG. 10 is a cross-sectional diagram showing a process for forming a pixel electrode. An ITO film having a thickness of approximately 40 nm is disposed as the pixel electrode 20 by the spattering method, and the resist is printed by the printing method. After the resist is baked, the resist adhered to an undesired region is removed or reduced in size by the thinning processing shown in FIG. 2B. Then the resist is again baked, and the pixel electrode 20 is subjected to the wet etching. Since this process of forming the pixel electrode 20 often remains the resist, the pixel electrode 20 can be formed by a general photolithography process using the photo-resist and the photo-mask, similarly to the process for forming the contact hole 19.

The TFT substrate completed by the above-described methods is bonded, after an orientation film is printed, with a color filter substrate on which a seal and spacer region are formed. After liquid crystal is injected thereto, the holes are sealed, and an optical film such as a polarizing plate is affixed to complete a liquid crystal display panel. In addition, in a case where the color filter is formed on the TFT substrate, in place of the color filter substrate, an opposed substrate on which a transparent electrode is formed is bonded with the COT substrate.

In this way, in a case where a resist is needed to be repeatedly formed for processes such as etching, the number of processes can be reduced by forming the resist by the printing method. Further, by carrying out the thinning processing after the resist is printed, the resist adhered to an undesired region can be removed or reduced in size to the extent where a problem is not caused. In addition, in a case where the line pattern is formed by the paste including conductive metal particles, the paste is also formed by the printing method, and the thinning processing is carried out to remove the paste adhered to an undesired region or reduce the size thereof to the extent where a problem is not caused. In other words, according to these effects, the generation of drawbacks can be suppressed to improve the yielding percentage.

It should be noted that, although the thinning processing is applied to an entire processes of forming a resist by using the printing method in the above descriptions, it only has to be applied to at least one of the processes.

### SECOND EXEMPLARY EMBODIMENT OF THE PRESENT INVENTION

Next, production equipment for a liquid crystal panel according to a second embodiment of the present invention is described below by referring to FIG. 11. FIG. 11 is a schematic diagram showing a configuration of printing equipment according to the second embodiment.

In the above-described first embodiment, the resist is printed by well-known printing equipment before the resist is subjected to the thinning processing such as plasma ashing, developing processing or other etching methods. If the process for printing the resist by the printing method and the process for thinning the resist are carried out in the same equipment, the number of the processes can be further reduced.

FIG. 11 is a diagram showing an example of printing equipment according to the second embodiment. In FIG. 11, the resist ejected from a coating device 104 is coated to a silicon blanket 108 via silicon sheet 102, and the resist is transferred from the silicon blanket 108 to substrate sheet 105 by which the resist of the silicon blanket 108 is partly removed by a convex portion 110 having patterns corresponding to a position where a pattern is not residual on the substrate sheet 105.

These processes can be carried out by conventional printing equipment. However, in the printing equipment according to the present embodiment, a printing film thinning unit 113 and baking units 112 and 114 are further. provided, if necessary.

Then, substrate sheet 105 on which the resist is printed is conveyed by a conveyance device (not shown) to the baking unit 112 and to the printing film thinning unit 113 when the resist is cured for some extent. In the following, the resist is subjected to the thinning processing by plasma etching, developing, or other etching methods such that a film thickness of the resist becomes half. Next, the substrate sheet 105 is conveyed to the baking unit 114, and water adhered by the developing processing, or the like, is removed therein, followed by the process of etching processing.

In a case where this printing film thinning processing unit 113 is a plasma ashing device, or the like, the baking units 112 and 114 can be omitted. FIG. 11 is an example of equipment for printing a resist for a four-colored color filter, but not only for the color filter, the equipment can be used for printing a photo-resist used for the TFT production manhour, a non-photosensitive resist excluding a photosensitive agent, conductive paste incorporating metal particles, or the like. In addition, the printing equipment is not limited for inkjet printing, off-set printing, screen printing, or, the like.

It should be noted that in each of the above embodiments, the descriptions are given by taking etching as an example of processing using the printing pattern, other methods capable of using the printing pattern as a mask (for example, ion injection) can be also carried out.

The above-described configuration of the present invention is not limited to be applied to the manufacturing of a substrate forming a LCD, but can be applied to the manufacturing of a substrate forming an Electro Luminescence displaying device, the manufacturing of a substrate forming a semiconductor device, or the like.

First, by partly using the printing method of the present invention, a method for manufacturing a substrate configuring LCD will be described here.

The method for manufacturing the substrate configuring LCD, which partly uses the printing method of the present invention, includes at least any one of the steps of a printing process for forming by the printing method a printed pattern made of an etching resistant member on etching film formed on a substrate, a thinning process for thinning the printed pattern by dry etching or wet etching, an etching process for etching the etching film by using the thinned printed pattern as a mask, a baking process for applying heat to the printed pattern at the time of at least either between the printing process and the thinning process, or after the thinning process.

In addition, in the above-described process of the thinning processing, the thinning processing can be carried out under the conditions that the etching member adhered to a region other than the region where a printed pattern is formed, or conductive member is removed or reduced in size. Further, the dry etching can include the plasma ashing, and the wet etching can include developing processing.

Further, the method for manufacturing the substrate configuring LCD, which partly uses the printing method of the present invention, includes the steps of a printing process for forming by the printing method a printed pattern made of the conductive member incorporating the conductive particles on the substrate, a thinning process for thinning the printed pattern by the dry etching or the wet etching, and a baking process for applying heat to the printed pattern at the time of at least either between the printing process and the thinning process, or after the thinning process.

Next, by partly using the printing method of the present invention, a method for manufacturing a substrate configuring organic EL display device will be described.

The method for manufacturing the substrate configuring organic EL display device, which partly uses the printing method of the present invention, includes the steps of a printing process for forming by the printing method a printed pattern made of an etching resistant member on etching film formed on the substrate, a thinning process for thinning the printed pattern by dry etching or wet etching, and an etching process for etching the etching film by using the thinned printed pattern as a mask.

Further, the method for manufacturing the substrate configuring organic EL display device, which partly uses the printing method of the present invention, includes the steps of a printing process for forming by the printing method a printed pattern made of a conductive member incorporating conductive particles on a substrate, and a thinning process for thinning the printed pattern by dry etching or wet etching.

As described above, in the processing using the printed pattern according to the present invention, the printed pattern is formed by using an etching resistant member such as a resist, and processing such as plasma ashing, developing processing, or the like is added for thinning the etching resistant member before etching is carried out by using the printed pattern as a mask.

Therefore, even when the etching resistant member adheres to an undesired region, the adhered etching resistant member is removed or reduced in size so that the etching film does not remain in the lower portion of the adhered etching resistant member or can be reduced to be substantially small.

In addition, the processing such as plasma ashing and developing processing for thinning the conductive member is added after the printed pattern is formed by using the conductive member incorporating the conductive metal particles. Therefore, even when the conductive member adheres to an undesired region, the adhered conductive member can be removed or reduced in size.

Thus, according to the processing using the printed pattern of the present invention, the generation of drawbacks such as line short circuit, point defect by pattern residual, or the like can be suppressed, and the reduction of the number of production manhour and the improvement of yielding percentage can be achieved at the same time.

It is apparent that the present invention is not limited to the above embodiments, but can be modified and changed without departing from the scope and spirit of the invention.

What is claimed is:

1. A method for printing a printed pattern, comprising the steps of:
a printing process for forming by using a printing method a printed pattern made of an etching resistant member on an etching film formed on a substrate;
a thinning process for thinning the printed pattern by dry etching or wet etching; and
an etching process for etching the etching film by using the thinned printed pattern as a mask.

2. The method for printing the printed pattern according to claim 1, wherein the etching resistant member is a photosensitive resist or non-photosensitive resist.

3. A method for printing a printed pattern, comprising the steps of:
a printing process for forming by using a printing method a printed pattern made of a conductive member incorporating conductive particles on a substrate; and
a thinning process for thinning the printed pattern by dry etching or wet etching.

4. The method for printing the printed pattern according to claim 1, wherein a baking process for applying heat to the printed pattern is added at least either between the printing process and the thinning process, or after the thinning process.

5. The method for printing the printing pattern according to claim 2, wherein a baking process for applying heat to the printed pattern is added at least either between the printing process and the thinning process, or after the thinning process.

6. The method for printing the printing pattern according to claim 3, wherein a baking process for applying heat to the printed pattern is added at least either between the printing process and the thinning process, or after the thinning process.

7. The method for printing the printed pattern according to claim 1, wherein the thinning process is carried out under the conditions that the etching resistant member adhered to a region other than the region where the printed pattern is formed or the conductive member can be removed or reduced in size.

8. The method for printing the printed pattern according to claim 3, wherein the thinning process is carried out under the conditions that the etching resistant member adhered to a region other than the region where the printed pattern is formed or the conductive member can be removed or reduced in size.

9. The method for printing the printed pattern according to claim 1, wherein the dry etching includes plasma ashing and the wet etching includes developing processing.

10. The method for printing the printed pattern according to claim 3, wherein the dry etching includes plasma ashing and the wet etching includes developing processing.

11. Production equipment for forming a printed pattern, comprising:
means which forms the printed pattern made of a conductive member incorporating an etching resistant member or conductive particles on a substrate; and
thinning processing means for thinning the printed pattern by dry etching or wet etching.

12. The production equipment for forming the printed pattern according to claim 11, wherein the etching resistant member is a photosensitive resist or non-photosensitive resist.

13. The production equipment for forming the printed pattern according to claim 11, wherein baking means is further included.

14. The production equipment for forming the printed pattern according to claim 11, wherein the dry etching includes plasma ashing and the wet etching includes developing processing.
